(19) United States
(12) Patent Application Publication
(10) Pub. No.: US 2024/0365608 A1
(43) Pub. Date: Oct. 31, 2024

(54) DRIVE BACKPLANE AND DISPLAY PANEL

(71) Applicants: Hefei Xinsheng Optoelectronics Technology Co., Ltd., Hefei, Anhui (CN); BOE Technology Group Co., Ltd., Beijing (CN)

(72) Inventors: Jingang FANG, Beijing (CN); Luke DING, Beijing (CN)

(21) Appl. No.: 18/028,944

(22) PCT Filed: Jun. 24, 2022
(86) PCT No.: PCT/CN2022/101042

§ 371 Date: Mar. 28, 2023

(51) Int. Cl. H10K 59/131; H10K 59/121

(52) U.S. Cl. CPC H10K 59/131; H10K 59/1216

(57) ABSTRACT

Provided is drive backplane. The drive backplane includes: a substrate, including a plurality of light transmitting regions and a plurality of sub-pixel regions; a pixel drive circuit and an anode block that are disposed in the sub-pixel region, the pixel drive circuit being electrically connected to the anode block; and repair lines and repair electrodes that are disposed in the light transmitting regions, an end of the repair line being spaced from the repair electrode; wherein, an end, departing from the repair electrode, of the repair line is electrically connected to the anode block in a first sub-pixel region, the repair electrode is electrically connected to the anode block in a second sub-pixel region.

### CROSS-REFERENCE TO RELATED APPLICATION

This application is a U.S. national phase application based on PCT/CN2022/101042, filed on Jun. 24, 2022, the disclosure of which is incorporated herein by reference in its entirety.

### TECHNICAL FIELD

The present application related the field of display technology, and in particular to a drive backplane and a display panel.

### BACKGROUND OF THE INVENTION

Currently, transparent display devices are gaining more and more popularity among consumers because of their display functions and perspective effects.

### SUMMARY OF THE INVENTION

Embodiments of the present application provide a drive backplane and a display panel that can improve the display effect of the display device. The technical solutions are as follows.

According to some embodiments of the present disclosure, a drive backplane is provided. The drive backplane includes: a substrate, including a plurality of light transmitting regions and a plurality of sub-pixel regions;
a pixel drive circuit and an anode block that are disposed in the sub-pixel region, the pixel drive circuit being electrically connected to the anode block; and
repair lines and repair electrodes that are disposed in the light transmitting regions, an end of the repair line being spaced from the repair electrode;
wherein, for any of the repair lines and the repair electrodes in the light transmitting region, an end, departing from the repair electrode, of the repair line is electrically connected to the anode block in a first sub-pixel region, wherein the repair electrode is electrically connected to the anode block in a second sub-pixel region, the first sub-pixel region is a sub-pixel region of the plurality of sub-pixel regions disposed on one side of the light transmitting region, and the second sub-pixel region is a sub-pixel region the plurality of sub-pixel regions disposed on the other side of the light transmitting region.

In some embodiments, at least some of the repair lines and the repair electrodes are arranged in a same layer as the anode block and are made of a same material as the anode block.

In some embodiments, the repair line includes a repair line body, and an auxiliary repair electrode connected to an end, close to the repair electrode, of the repair line body, the auxiliary repair electrode being spaced from the repair electrode;
wherein the repair line body is made of a transparent conductive material, and the auxiliary repair electrode is arranged in a same layer as the repair electrode and is made of a same material as the repair electrode.

In some embodiments, the repair line body is closer to the substrate relative to the auxiliary repair electrode, an orthographic projection of the auxiliary repair electrode on the substrate is within an orthographic projection of the repair line body on the substrate, and an orthographic projection of the repair line body on the substrate is overlapped with an orthographic projection of the anode block in the first sub-pixel region on the substrate.

In some embodiments, the drive backplane further includes: a landing electrode disposed in the light transmitting region, wherein at least one of the auxiliary repair electrode and the repair electrode is insulated from the landing electrode, the landing electrode is closer to the substrate relative to the repair line body, and an orthographic projection of the repair electrode on the substrate and an orthographic projection of the auxiliary repair electrode on the substrate are within an orthographic projection of the landing electrode on the substrate.

In some embodiments, the repair electrode and the anode block in the second sub-pixel region are in an integral structure.

In some embodiments, at least two adjacent sub-pixel regions are configured to form a pixel region, and the drive backplane further includes a plurality of sense signal lines disposed on the substrate, one of the sense signal line being electrically connected to each of the pixel drive circuits in a row of the pixel regions;
wherein in response to the repair line in the light transmitting region adjacent to the sense signal line being disposed on a side, close to the sense signal line, of the light transmitting region, a plurality of bumps are defined on a side, close to the light transmitting region, of the sense signal line.

In some embodiments, the pixel drive circuit includes: a plurality of transistors disposed in a same layer, each of the transistors including: a first electrode, a second electrode and a gate electrode, the first electrode, the second electrode, and the gate electrode are disposed in a same layer and are made of a same material.

In some embodiments, the transistor further includes: an active layer, wherein the active layer is insulated from the gate electrode and coupled to the first electrode and the second electrode; and
the drive backplane further includes: a light shieling layer disposed in the sub-pixel region, wherein the light shielding layer is closer to the substrate relative to the transistor, and in one sub-pixel region, an orthographic projection of a channel region in the active layer of at least one of the transistors of the pixel drive circuit on the substrate is within an orthographic projection of the light shieling layer on the substrate.

In some embodiments, the pixel drive circuit further includes: a storage capacitor, including two capacitor electrodes opposite to each other, wherein one of the two capacitor electrodes is arranged in a same layer as the light shieling layer and is made of a same material as the light shieling layer, and the other of the two capacitor electrodes is arranged in a same layer as the gate electrode and is made of a same material as the gate electrode.

In some embodiments, the active layer is closer to the substrate relative to the gate electrode, and an auxiliary capacitor electrode is disposed between the two capacitor electrodes, wherein the auxiliary capacitor electrode is insulated from each of the capacitor electrodes, and the auxiliary capacitor electrode is arranged in a same layer as the active layer and is made of a same material as the active layer.

In some embodiments, the drive backplane further includes: a buffering layer, disposed between the auxiliary capacitor electrode and one of the two capacitor electrodes, and a gate insulating layer disposed between the auxiliary capacitor electrode and the other of the two capacitor electrodes, the buffering layer is closer to the substrate relative to the gate insulating layer.

In some embodiments, the drive backplane further includes: a plurality of gate lines and a plurality of data lines that are disposed on the substrate, wherein the gate line is electrically connected to each of the pixel drive circuits in one row of the sub-pixel regions, and the data line is electrically connected to each of the pixel drive circuits in one column of the sub-pixel regions;

wherein the gate line is arranged in a same layer as the light shieling layer and is made of a same material as the light shieling layer, and the data lines include: a first sub-data line and a second sub-data line that are stacked and electrically connected to each other, the first sub-data line is arranged in a same layer as the first electrode and the second electrode of the transistor and is made of a same material as the first electrode and the second electrode of the transistor, and the second sub-data line is arranged in a same layer as the gate line and is made of a same material as the gate line.

In some embodiments, the drive backplane further includes: power signal lines disposed on the substrate, wherein the power signal line includes: a plurality of first sub-power signal lines disposed parallel to the gate lines, and a plurality of second sub-power signal lines disposed parallel to the data lines, the first sub-power line is electrically connected to the second sub-power signal lines, and the first sub-power signal line is electrically connected to each of the pixel drive circuits in one row of the sub-pixel regions.

In some embodiments, the second sub-power signal line includes: a first signal line section and a second signal line section that are stacked and electrically connected to each other, wherein the first signal line section is arranged in a same layer as the first electrode and second electrode of the transistor and is made of a same material as the first electrode and second electrode of the transistor, the second signal line section and the first sub-power signal line are arranged in a same layer as the gate line and are made of a same material as the gate line.

According to some embodiments of the present disclosure, a display panel is provided, including: a drive backplane, a light emitting layer and a cathode layer disposed on the drive backplane, the drive backplane being the drive backplane described above.

### BRIEF DESCRIPTION OF DRAWINGS

In order to describe the technical solutions in the embodiments of the present disclosure more clearly, the following briefly describes the accompanying drawings required for describing the embodiments. Apparently, the accompanying drawings in the following description show merely some embodiments of the present disclosure, and those of ordinary skill in the art can still derive other drawings from these accompanying drawings without creative efforts.

FIG. 1 is a top view of a common display panel at present;

FIG. 2 is a top view of a drive backplane according to some embodiments of present application;

FIG. 3 is a cross-sectional view at A-A′ of the drive backplane illustrated in FIG. 2;

FIG. 4 is a schematic diagram of the structure of the display panel according to some embodiments of the present application;

FIG. 5 is a schematic diagram of a film layer of a repaired drive backplane according to some embodiments of the present application;

FIG. 6 is a top view of a pixel region according to some embodiments of the present application;

FIG. 7 is a cross-sectional view at B-B′ of the pixel region illustrated in FIG. 6;

FIG. 8 is a schematic diagram of the structure of a pixel drive circuit disposed in a sub-pixel region of the drive backplane illustrated in FIG. 2;

FIG. 9 is a cross-sectional view at C-C′ of the pixel drive circuit illustrated in FIG. 8;

FIG. 10 is a circuit diagram of a pixel drive circuit according to some embodiments of the present application;

FIG. 11 is a schematic diagram of a film layer structure of the drive backplane according to some embodiments of the present application;

FIG. 12 is a top view of a first conductive layer according to some embodiments of the present application;

FIG. 13 is a top view of the first conductive layer and an active layer that are stacked according to some embodiments of the present application;

FIG. 14 s a top view of the first conductive layer and a second conductive layer that are stacked according to some embodiments of the present application;

FIG. 15 is a top view of the first conductive layer, the second conductive layer, and a third conductive layer that are stacked according to some embodiments of the present application;

FIG. 16 is a schematic diagram of a pixel definition layer according to some embodiments of the present application;

FIG. 17 is a schematic diagram of another pixel definition layer according to some embodiments of the present application;

FIG. 18 is a schematic diagram of a display panel according to some embodiments of the present application; and

FIG. 19 is a cross-sectional view at D-D′ of the display panel illustrated in FIG. 18.

### DETAILED DESCRIPTION

For clearer descriptions of the objectives, technical solutions, and advantages of the present disclosure, the following further describes implementations of the present disclosure in detail with reference to the accompanying drawings.

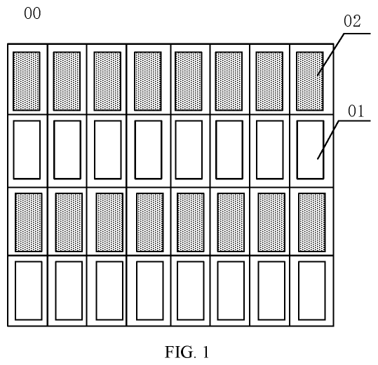

Referring to FIG. 1, FIG. 1 is a top view of a common display panel at present. The display panel 00 has a plurality of light transmitting regions 01 and a plurality of sub-pixel regions 02. Each of the sub-pixel regions 01 of the display panel 00 can emit light outwardly, such that the display panel 00 can display a picture and the transparent display device including the display panel 00 has a display function. Each of the light transmitting regions 02 of the display panel 00 is configured to transmit ambient light, such that the transparent display device including the display panel 00 has a perspective effect.

A pixel drive circuit and a light-emitting device is disposed in the sub-pixel region 01 of the display panel 00. The pixel drive circuit is electrically connected to the light-emitting device, and the light-emitting device can be driven to emit light outwardly by the pixel drive circuit. However, in the case that the pixel drive circuit in a certain sub-pixel region 01 does not work due to a short circuit or a broken circuit, the light-emitting device in the sub-pixel region 01 is not be able to emit light, resulting in a lower yield rate of the display panel 00, which in turn results in a poorer display effect of the transparent display device.

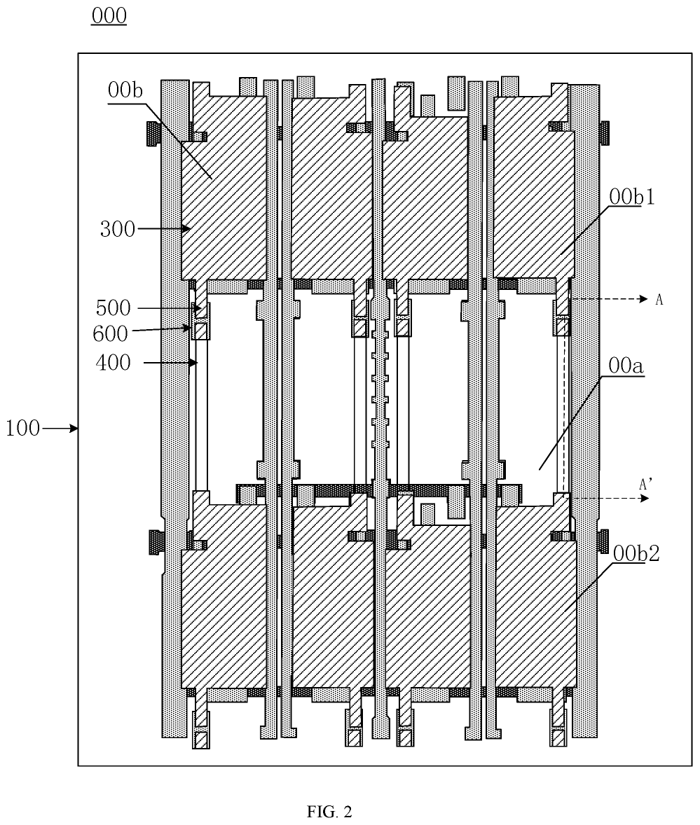

Referring to FIG. 2, FIG. 2 is a top view of a drive backplane according to some embodiments of the present application. The drive backplane 000 includes: a substrate 100, a pixel drive circuit 200 (not labeled in FIG. 2 and labeled in later figures), an anode block 300, repair lines 400, and repair electrodes 500.

The substrate 100 of the drive backplane 000 has a plurality of light transmitting regions 00a and a plurality of sub-pixel regions 00b.

The pixel drive circuit 200 and the anode block 300 of the drive backplane 000 are both disposed in the sub-pixel regions 00b, and the pixel drive circuit 200 are electrically connected to the anode block 300 in the same sub-pixel region 00b. The anode block 300 is an anode block in the light-emitting device. In the case that the light-emitting layer and the cathode layer are formed in the light-emitting device on the drive backplane 000, the anode block in the light-emitting device is driven by the pixel drive circuit 200 to enable the light-emitting device to emit light.

Both the repair line 400 and the repair electrode 500 in the drive backplane 000 are disposed in the light transmitting region 00a, and an end of the repair line 400 is spaced form the repair electrode 500 in the same light transmitting region 00a.

For the repair line 400 and repair electrode 500 in any light transmitting regions 00a1, the end of the repair line 400 departing from the repair electrode 500 is electrically connected to the anode block 300 in the first sub-pixel region 00b1. The repair electrode 500 is electrically connected to the anode block 300 in the second sub-pixel region 00b2. The first sub-pixel region 00b1 is a sub-pixel region 00b of the plurality of sub-pixel regions 00b disposed on one side of this transmitting region 00a, and the second sub-pixel region 00b2 is a sub-pixel region 00b of the plurality of sub-pixel regions 00b disposed on the other side of this transmitting region 00a.

In some embodiments of the present application, the detection device can detect whether the pixel drive circuit 200 in each sub-pixel region 00b of the drive backplane 000 is capable of functioning properly. The detection device can send a drive signal to the pixel drive circuit 200 and detect whether the drive voltage loaded on the anode block 300 electrically connected to the pixel drive circuit 200 is normal. In the case that the drive voltage loaded on the anode block 300 is normal, the pixel drive circuit 200 electrically connected to the anode block 300 can work normally and the light-emitting device containing the anode block 300 can emit light normally. In the case that the drive voltage loaded on the anode block 300 is abnormal, the pixel drive circuit 200 electrically connected to the anode block 300 is not able to operate normally and the light-emitting device containing the anode block 300 is not able to emit light normally.

In the present application, in response to detecting that the pixel drive circuit 200 in a sub-pixel region (e.g., a first sub-pixel region 00b1) is not functioning properly, the end of the repair line 400 and the repair electrode 500 in the light transmitting region 00a adjacent to the first sub-pixel region 00b1 is heated by the laser repair device, such that the end of the repair line 400 and the repair electrode 500 are fused together by the heat. That is, the repair line 400 and the repair electrode 500 can be electrically connected to each other. In this way, the anode block 300 in the first sub-pixel region 00b1 is electrically connected to the anode block 300 in the second sub-pixel region 00b2 by the repair line 400 and the repair electrode 500. In this way, in the process that the anode block 300 in the second sub-pixel region 00b2 is driven by the pixel drive circuit 200 in the second sub-pixel region 00b2, the anode block 300 in the second sub-pixel region 00b2 can transmit the drive signal to the anode block 300 in the first sub-pixel region 00b1 to enable the pixel drive circuit 200 in the second sub-pixel region 00b2 to drive the anode blocks 300 in the second sub-pixel region 00b2 and the first sub-pixel region 00b1.

As can be seen, in the case that the pixel drive circuit 200 in the first sub-pixel region 00b1 does not work properly, the pixel drive circuit 200 in the second sub-pixel region 00b2 can drive the anode block 300 in the first sub-pixel region 00b1, such that the light emitting device in the first sub-pixel region 00b1 can also emit light properly, improving the yield rate of the display panel integrated with the drive backplane, and improving the display effect of the transparent display device integrated with the display panel.

In summary, embodiments of the present application provide a drive backplane, including: a substrate, a pixel drive circuit, an anode block, a repair line, and a repair electrode. In response to detecting that the pixel drive circuit in a sub-pixel region (e.g., a first sub-pixel region) is not functioning properly, the end of the repair line and the repair electrode in the light transmitting region adjacent to the first sub-pixel region can be heated by a laser repair device, such that the end of the repair wire and the repair electrode are fused together by heat. That is, the repair line and the repair electrode can be electrically connected to each other. In this way, the anode block in the first sub-pixel region is electrically connected to the anode block in the second sub-pixel region by the repair line and the repair electrode. In this way, during the process of the anode block in the second sub-pixel region being driven by the pixel drive circuit in the second sub-pixel region, the anode block in the second sub-pixel region can transmit the drive signal to the anode block in the first sub-pixel region, such that the pixel drive circuit in the second sub-pixel region can drive the anode blocks in the second sub-pixel region and the first sub-pixel region simultaneously. Therefore, in the case that the pixel drive circuit in the first sub-pixel region does not work properly, the anode block in the first sub-pixel region can be driven by the pixel drive circuit in the second sub-pixel region, such that the light-emitting device in the first sub-pixel region can also emit light properly, improving the yield rate of the display panel integrated with the drive backplane, and improving the display effect of the transparent display device integrated with the display panel.

In the present application, because the conductive layer where the anode block 300 is disposed is usually the outermost conductive layer in the drive backplane 000. Therefore, in order to facilitate subsequent fusion of the end of the repair line 400 to the repair electrode 500, it is necessary to ensure that at least some of the repair lines 400 and the repair electrodes 500, are arrange in a same layer as the anode block 300 and are made of the same material as the anode block 300. In this way, the conductive layer where at least some of the repair lines 400 and the repair electrodes 500 are disposed is also the outermost conductive layer in the drive backplane 000, and the outermost conductive layer in the drive backplane 000 can be treated directly to fuse the end of the repair line 400 to the repair electrode 500 in the case that the repair operation is performed on the drive backplane 000.

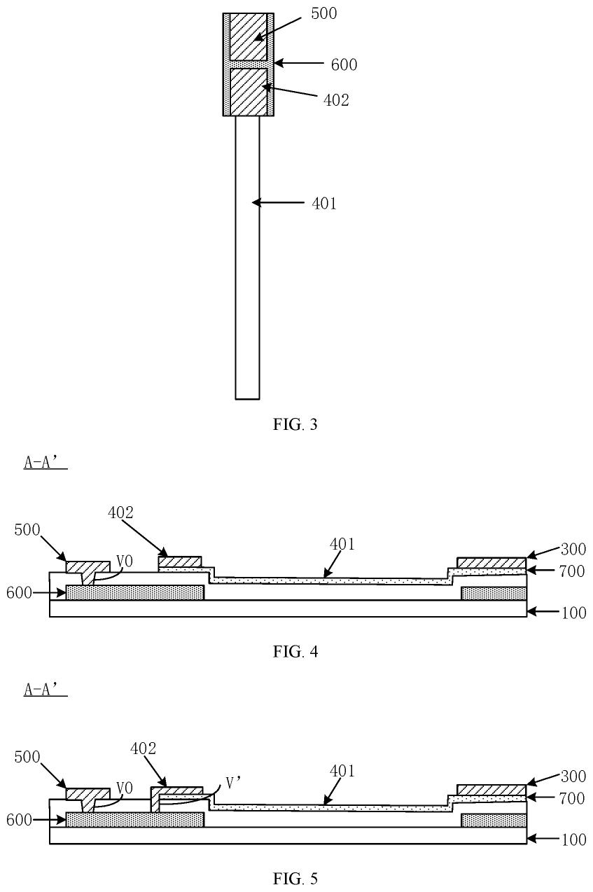

For example, referring to FIG. 3, FIG. 3 is a schematic diagram of a position relationship between a repair line and a repair electrode according to some embodiments of the present application. The repair line 400 includes: a repair line body 401, and an auxiliary repair electrode 402 connected to an end, close to the repair electrode 500, of the repair line body 401, and the auxiliary repair electrode 402 is spaced from the repair electrode 500. The repair line body 401 is made of a transparent conductive material, and the auxiliary repair electrode 402 is arranged in a same layer as repair electrode 500 and is made of a same material as the repair electrode 500, that is, auxiliary repair electrode 402 and repair electrode 500 are formed by one-time patterning process.

In this case, because the repair line body 401 is made of a transparent conductive material, ambient light can pass through the repair line body 401 and the light transmitting region 00a, which can increase the light transmission rate of the drive backplane 000 while ensuring that the drive backplane 000 can be repaired, making the transparent display device integrated with this drive backplane 000 have a better perspective effect. For example, the repair line body 401 is made of indium tin oxide (ITO).

It should be noted that the repair line body 401 is made of a transparent conductive material, while the auxiliary repair electrode 402 is typically made of a non-transparent conductive material (e.g., a metallic material). Therefore, the repair line body 401 and the auxiliary repair electrode 402 are not formed by one-time patterning process, i.e., the repair line body 401 and the auxiliary repair electrode 402 are arranged in different layers. In the present application, an insulating layer is not arranged between the conductive layer where the repair line body 401 is disposed and the conductive layer where the auxiliary repair electrode 402 is disposed. In this way, the repair line body 401 and the auxiliary repair electrode 402 can be directly electrically connected to each other by lap connection. Because the auxiliary repair electrode 402 and the anode block 300 are arranged in the same layer and are made of the same material, the repair line body 401 and the anode block 300 in the first sub-pixel region 00b1 can also be electrically connected to each other directly by lap connection.

Optionally, as shown in FIGS. 3 and 4, FIG. 3 is a cross-sectional view at A-A′ of the drive backplane illustrated in FIG. 2. The repair line body 401 is closer to the substrate 100 relative to the auxiliary repair electrode 402. The orthographic projection of the auxiliary repair electrode 402 on the substrate 100 is within the orthographic projection of the repair line body 401 on the substrate 100, such that an effective electrical connection between the auxiliary repair electrode 402 and the repair line body 401 can be ensured. The orthographic projection of the repair line body 401 on the substrate 100 is overlapped with the orthographic projection of the anode block 300 within the first sub-pixel region 00b1 on the substrate 100, such that an effective electrical connection can be ensured between the repair line body 401 and the anode block 300 in the first sub-pixel region 00b1.

In the present application embodiment, with continued reference to FIG. 2, the repair electrode 500 and the anode block 300 in the second sub-pixel region 00b2 are in an integral structure. In this case, the drive voltage on the repair electrode 500 and the anode block 300 in the second sub-pixel region 00b2 are consistent, enabling an effective electrical connection between the repair electrode 500 and the anode block 300 in the second sub-pixel region 00b2.

Optionally, as shown in FIGS. 2 and 4, the drive backplane 000 further includes: a landing electrode 600 disposed in the transmitting region 00a. In one light transmitting region 00a, at least one of the auxiliary repair electrode 402 and the repair electrode 500 is insulated from the landing electrode 600. The landing electrode 600 is closer to the substrate 100 relative to the repair line body 401, and the orthographic projection of the repair electrode 500 on the substrate 100 and the orthographic projection of the auxiliary repair electrode 402 on the substrate 100 are disposed within the orthographic projection of the landing electrode 600 on the substrate 100.

Example, a passivation layer 700 is disposed between the conductive layer to which the auxiliary repair electrode 402 and the repair electrode 500 belong and the conductive layer to which the landing electrode 600 belongs. In the case that the auxiliary repair electrode 402 and the repair electrode 500 are insulated from the landing electrode 600, the portion of the passivation layer 700 disposed between the auxiliary repair electrode 402 and the landing electrode 600 is not provided with a via hole, and the portion of the passivation layer 700 disposed between the repair electrode 500 and the landing electrode 600 is not provided with a via hole.

In the case that one of the auxiliary repair electrode 402 and the repair electrode 500 is insulated from the landing electrode 600 and the other is coupled to the landing electrode 600 (e.g., the auxiliary repair electrode 402 is insulated from the landing electrode 600 and the repair electrode 500 is coupled to the landing electrode 600), the portion of the passivation layer 700 disposed between the auxiliary repair electrode 402 and the landing electrode 600 is not provided with a via hole, and the portion of the passivation layer 700 disposed between the repair electrode 500 and the landing electrode 600 is provided with an via hole V0, such that the repair electrode 500 can be coupled to the landing electrode 600 through the via hole V0.

Assuming that the detection device detects that the pixel drive circuit 200 in the first sub-pixel region 00b1 in the drive backplane 000 is not working properly, the passivation layer 700 at the position of the side of the repair electrode 402 toward the repair electrode 500 can be cut by the laser repair device. In this way, referring to FIG. 5, FIG. 5 is a schematic diagram of a film layer of a repaired drive backplane according to some embodiments of the present application. A cutting hole V′ is formed at the position of the auxiliary repair electrode 402 toward the side of the repair electrode 500 in the passivation layer 700. The auxiliary repair electrode 402 can lap to the landing electrode 600 in the cutting hole V′ upon being melted by heat. In the case that the auxiliary repair electrode 402 in the cutting hole V′ is cured, the auxiliary repair electrode 402 is electrically connected to the landing electrode 500. Because the landing electrode 600 is electrically connected to the repair electrode 500, it is possible to ensure that the auxiliary repair electrode 402 is electrically connected to the repair electrode 500 by the landing electrode 600.

In some embodiments of the present application, at least two sub-pixel regions 00b in the drive backplane 000 arranged adjacent to each other form a pixel region. The individual sub-pixel regions 00b in a pixel region have different types. Upon integrating the drive backplane 000 in the display panel, portions of the display panel that are disposed in one type of subpixel region display one color, and portions of the display panel that are disposed in different types of subpixel regions display different colors.

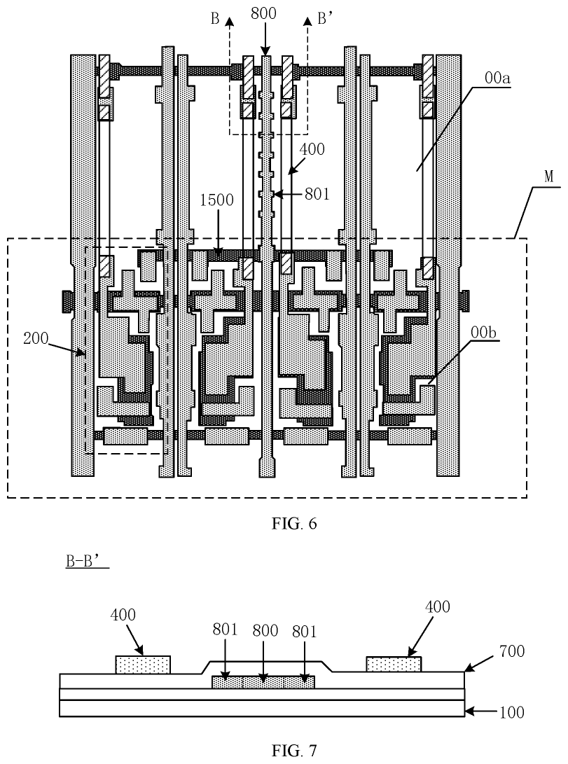

Exemplarily, referring to FIG. 6, FIG. 6 is a top view of a pixel region according to some embodiments of the present application. A sub-pixel region M in the drive backplane 000 includes four adjacent rows of sub-pixel regions 00b. Upon integrating the drive backplane 000 in the display panel, portions of the display panel disposed in the four adjacent rows of sub-pixel regions 00b display red, green, blue, and white respectively.

In the present application, as shown in FIG. 6, the plurality of sub-pixel regions 00b in the drive backplane 000 are arranged in a plurality of rows, the plurality of light transmitting regions 00a are arranged in a plurality of rows, and the plurality of rows of sub-pixel regions 00b and the plurality of rows of light transmitting regions 00a are alternately distributed one after the other. In other possible implementations, the plurality of sub-pixel regions 00b are arranged in a plurality of columns, the plurality of light transmitting regions 00a are arranged in a plurality of columns, and the plurality of sub-pixel regions 00b and the plurality of light transmitting regions 00a are alternately distributed one after the other, which is not limited in the embodiment of the application.

Optionally, as shown in FIG. 6, the drive backplane 000 also includes: a plurality of sense signal lines 800 disposed on the substrate 100. One sense signal line 800 is electrically connected to each of the pixel drive circuits 200 in a row of the pixel regions M.

In response to the repair line 400 in the light transmitting region 00a adjacent to the sense signal line 800 being disposed on a side of the light transmitting region 00a close to the sense signal line 800, a plurality of bumps 801 are disposed on a side of the sense signal line 800 close to the light transmitting region 00a. Exemplarily, assuming that, in the light transmitting region 00a distributed on both sides of the sense signal line 800, the repair lines are disposed on the side of the light transmitting region 00a close to the sense signal line 800, i.e., the sense signal line 800 is disposed between two adjacent repair lines 400. Both sides of the sense signal line 800 have a plurality of bumps 801, i.e., the sense signal line 800 is a serrated signal line.

In the present application, referring to FIG. 7, FIG. 7 is a cross-sectional view at B-B′ of the pixel region illustrated in FIG. 6. The sense signal line 800 is closer to the substrate 100 relative to the repair line 400. The sense signal line 800 is provided on the same layer as the landing electrode 600 and is made of the same material as the landing electrode 600 in the above embodiment. The sense signal line 800 has a passivation layer 700 on the side departing from the substrate 100, while the repair line 400 is disposed on the side of the passivation layer 700 departing from the substrate 100.

In this case, the portion of the passivation layer 700 covering the sense signal line 800 is raised outwardly relative to the other portions. In the case that the sense signal line 800 is a serrated signal line, the portion of the passivation layer 700 covering the sense signal line 800 is a serrated bump. In this way, in the process of forming the repair line 400 by the patterning process, the serrated bump in the passivation layer 700 can effectively remove the photoresist above the passivation layer 700, such that the short circuit phenomenon does not appear between the subsequently formed repair line 400 disposed on both sides of the sense signal line 800.

Optionally, as shown in FIG. 6, the drive backplane 000 can also include: auxiliary sense line 1500. The auxiliary sense line 1500 can be arranged in the same layer as the grid line and is made of the same material as the grid line in subsequent embodiments, that is, the auxiliary sense line 1500 and the grid line is formed by the one-time patterning process. The length of the auxiliary sense line 1500 is perpendicular to the length of the sense signal line 800, the auxiliary sense line 1500 can be electrically connected to the sense signal line 800, and the auxiliary sense line 1500 can be electrically connected to each of the pixel drive circuits 200 in the same pixel region M. Therefore, the sense signal line 800 is electrically connected to each of the pixel drive circuits 200 in the pixel region M by the auxiliary sense line 1500.

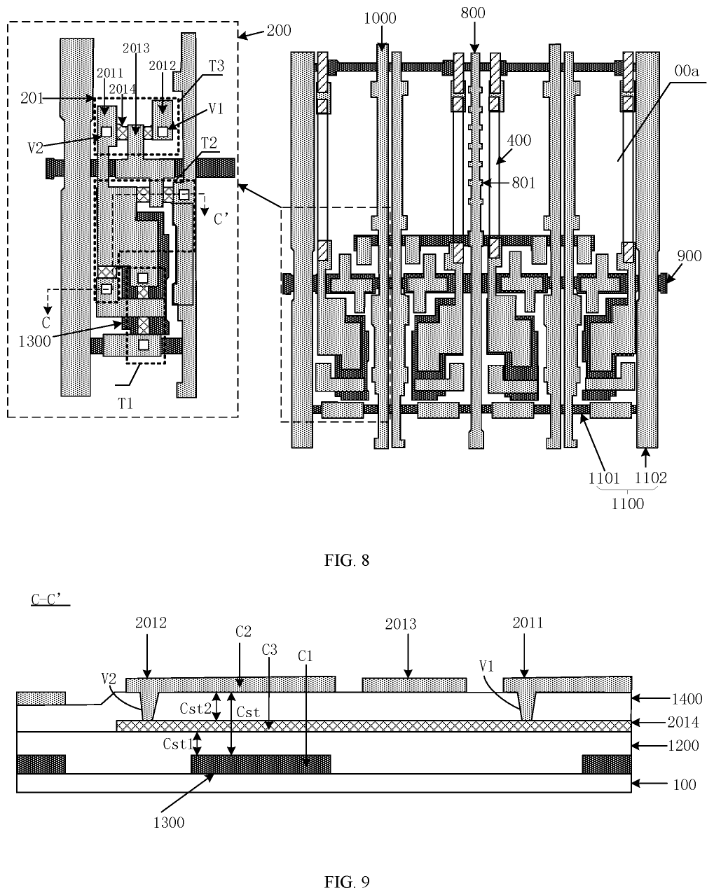

In the present application, as shown in FIG. 8, FIG. 8 is a schematic diagram of the structure of a pixel drive circuit disposed in a sub-pixel region of the drive backplane illustrated in FIG. 2. The pixel drive circuit 200 includes: a plurality of transistors 201 provided in the same layer. The transistors 201 have: a first electrode 2011, a second electrode 2012, and a gate electrode 2013, the first electrode 2011, the second electrode 2012 and the gate electrode 2013 being provided in a same layer and being made of a same material. That is, the first electrode 2011, the second electrode 2012 and the gate electrode 2013 in the transistor 201 are formed by one-time patterning process. In this way, the quantity of conductive layers in the drive backplane 000 can be effectively reduced, which can reduce the manufacturing cost of the drive backplane 000 and improve the preparation efficiency of the drive backplane 000.

It should be noted that the first electrode 2011 is one of the source electrode and drain electrode of the transistor 201, and the second electrode 2012 is the other of the source electrode and drain electrode of the transistor 201. Exemplarily, the plurality of transistors 201 in each pixel drive circuit 200 includes: a first transistor T1, a second transistor T2, and a third transistor T3.

Referring to FIG. 9, FIG. 9 is a cross-sectional view at C-C′ of the pixel drive circuit illustrated in FIG. 8. The transistor also has: an active layer 2014. The active layer 2014 is insulated from the gate electrode 2013 and coupled to the first electrode 2011 and the second electrode 2012. Exemplarily, the active layer 2014 is electrically connected to the first electrode 2011 through the via hole V1. The active layer 2014 is electrically connected to the second electrode 2012 through the via hole V2.

The drive backplane 000 further includes: a light shieling layer 1300 disposed in a sub-pixel region 00b, the light shieling layer 1300 being closer to the substrate 100 relative to the transistor 201 In the same sub-pixel region 00b, an orthographic projection of a channel region in the active layer 2014 of at least one transistor 201 of the pixel drive circuit 200 on the substrate 100 is within an orthographic projection of the light shieling layer 1300 on the substrate 100. Exemplarily, as shown in FIG. 7, the orthographic projection of the channel region in the active layer 2014 of the first transistor T1 in the pixel drive circuit 200 on the substrate 100 is within the orthographic projection of the light-shielding layer 1300 on the substrate 100.

In this case, in the case that external light shines on the channel region in the active layer 2014 of the transistor 201, photon-generated carriers may be generated in the channel region of the active layer 2014, resulting in a change in the open-state current of this transistor 201, which results in a change in the electrical properties of this transistor 201. In the case that the orthographic projection of the channel region in the active layer 2014 of the crystal light on the substrate 100 is within the orthographic projection of the light shieling layer 1300 on the substrate 100, the light shieling layer 1300 can block the external light from shining on the channel region in the active layer 2014, thus the influence of the external light on the electrical properties of the transistor 201 can be avoided, making the pixel drive circuit 200 more stable.

It should be noted that the ohm contact resistance of the portion of the active layer 2014 coupled to the first electrode 2011 and the second electrode 2012 is low. In one possible implementation, during the preparation of the active layer 2014, a gas such as ammonia, nitrogen or hydrogen is used to make the portion of the active layer 2014 coupled to the first electrode 2011 and the second electrode 2012 conductive without making other portions of the active layer 2014 (e.g., the channel region) conductive. In this way, it is ensured that the channel region in the active layer 2014 remains a semiconductor while the ohm contact resistance of the portion of the active layer 2014 coupled to the first electrode 2011 and the second electrode 2012 is low.

Optionally, referring to further FIG. 9, the pixel drive circuit 200 further includes: a storage capacitor Cst. The storage capacitor Cst has two capacitive electrodes opposite to each other. In the two capacitive electrodes, one capacitive electrode C1 is arranged in the same layer as the light shield layer 1300 and is made of the same material as the light shield layer 1300, and the other capacitive electrode C2 is arranged in the same layer as the gate electrode 2013 and is made of the same material as the gate electrode 2013. That is, the capacitor electrode C1 and the light shieling layer 1300 are formed by one-time patterning process, and the capacitor electrode C2 and the gate electrode 2013 are formed by one-time patterning process. In this way, the quantity of conductive layers in the drive backplane 000 can be further reduced, which can reduce the manufacturing cost of the drive backplane 000 and improve the preparation efficiency of the drive backplane 000.

In the embodiment of the application, as shown in FIG. 9, the active layer 2014 is closer to the substrate 100 relative to the gate electrode 2013, and an auxiliary capacitor electrode C3 is disposed between the two capacitor electrodes. The auxiliary capacitor electrode C3 is insulated from each capacitor electrode, and the auxiliary capacitor electrode C3 is arranged in the same layer as the active layer 2014 and is made of the same material as the active layer 2014. In this case, capacitor electrode C1 and auxiliary capacitor electrode C3 form a storage capacitor Cst1, and the other capacitor pole C2 and auxiliary capacitor electrode C3 also form a storage capacitor Cst2. In this way, the capacitance value of the storage capacitor Cst of the pixel drive circuit 200 is the sum of the capacitance value of this storage capacitor Cst1 and the capacitance value of the storage capacitor Cst2. In this way, the capacitance value of the storage capacitor Cst of the pixel drive circuit 200 can be effectively increased, and the stability of this pixel drive circuit 200 is improved.

Exemplarily, as shown in FIG. 9, the drive backplane 000 further includes: a buffering layer 1200 disposed between the auxiliary capacitor electrode C3 and one of the two capacitor electrodes C1, and a gate insulating layer 1400 disposed between the auxiliary capacitor electrode C3 and the other capacitor electrode C2 of the two capacitor electrodes, the buffering layer 1200 being closer to the gate insulating layer 1400 relative to the Substrate 100. The capacitor electrode C1 is insulated from the auxiliary capacitor electrode C3 by the buffering layer 1200, and capacitor electrode C2 is insulated from the auxiliary capacitor electrode C3 by the gate insulating layer 1400. It is to be noted that the gate electrode 2013 in the transistor 201 is insulated from the active layer 2014 by the gate insulating layer 1400.

Optionally, as shown in FIG. 8, the drive backplane 000 further includes: a plurality of gate lines 900 and a plurality of data lines 1000 disposed on the substrate 100, the gate line 900 being electrically connected to each of the pixel drive circuits 200 in one row of the sub-pixel regions 00b, and the data line 1000 being electrically connected to each of the pixel drive circuits 200 in one column of the sub-pixel regions 00b.

The grid line 900 is arranged in the same layer as the light shieling layer 1300 and is made of the same material as the light shieling layer 1300. That is, the grid line 900 and the light shieling layer 1300 are formed by one-time patterning process. The data line 1000 includes: a first sub-data line 1001 and a second sub-data line 1002 (not labeled in FIG. 7 and reflected in the accompanying drawings later) which are stacked and electrically connected to each other. The first sub-data line 1001 is arranged in a same layer as the first electrode 2011 and the second electrode 2012 of the transistor and is made of a same material as the first electrode 2011 and the second electrode 2012 of the transistor, and the second sub-data line 1002 is arranged in a same layer as the gate line 900 and has a same material as the gate line 900. That is, the first sub-data line 1001, the first electrode 2011 and the second electrode 2012 of the transistor are formed by one-time patterning process, and the second sub-data line 1002 and the gate line 900 are formed by one-time patterning process.

In this case, the first sub-data line 1001 and the second sub-data line 1002, which are stacked and electrically connected to each other, are able to reduce the impedance of the data line 1000 and reduce the influence of the data line 1000 on the drive voltage in the pixel drive circuit 200, which improves the drive effect of this pixel drive circuit 200.

Optionally, see further FIG. 8, the drive backplane 000 further includes: power signal lines 1100 disposed on the substrate 100, the power signal line 1100 including: a plurality of first sub-power signal lines 1101 disposed parallel to the gate line 900, and a plurality of second sub-power signal lines 1102 disposed parallel to the data line 1000, the first sub-power signal line 1101 being electrically connected to the second sub power supply signal lines 1102, and the first sub-power supply signal lines 1101 being electrically connected to each of the pixel drive circuits 200 in one row of sub-pixel regions.

The second sub-power signal line 1102 includes: a first signal line section 1102a and a second signal line section 1102b (not labeled in FIG. 8 and reflected in the accompanying drawings later) which are stacked and electrically connected to each other. The first signal line section 1102a is arranged in a same layer as the first electrode 2011 and the second electrode 2012 of the transistor 201 and is made of the same material as the first electrode 2011 and the second electrode 2012 of the transistor 201. That is, the first signal line section 1102a, the first electrode 2011 and the second electrode 2012 of the transistor 201 are formed by one-time patterning process. The second signal line section 1102b, the first sub-power signal line 1101 are arranged in a same layer as the gate line 900 and are made of the same material as the gate line 900. That is, the second signal line section 1102b, the first sub-power signal line 1101 and the gate line 900 are formed by one-time patterning process.

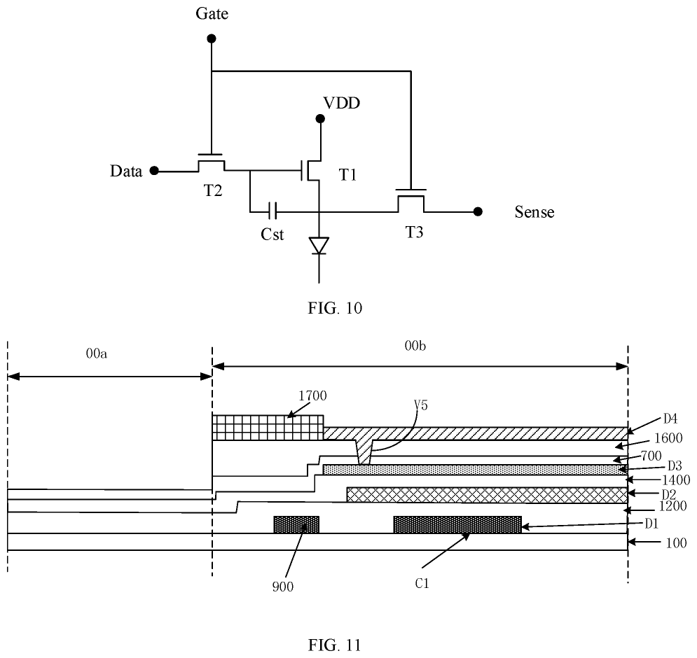

In some embodiments of the present application, referring to FIG. 8 and FIG. 10, FIG. 10 is a circuit diagram of a pixel drive circuit according to some embodiments of the present application. The pixel drive circuit 200 includes: a first transistor T1, a second transistor T2, a third transistor T3, and a storage capacitor Cst. The first electrode of the second transistor T2 is electrically connected to the data line 1000 (i.e., Data in FIG. 10), the second electrode of the second transistor T2 is electrically connected to the gate electrode of the first transistor T1 and one capacitor electrode of the storage capacitor Cst, and the second gate electrode of the second transistor T2 is electrically connected to the gate line 900 (i.e. Gate in FIG. 10). The first electrode of the first transistor T1 is electrically connected to the power signal line 1100 (i.e. VDD in FIG. 10), and the second electrode of the first transistor T1 is electrically connected to the anode block 300 in the first sub-pixel region 00b1, the other capacitor electrode of the storage capacitor Cst, and the first electrode of the third transistor T3. The second electrode of the third transistor T3 is electrically connected to the sense signal line 800 (also known as Sense in FIG. 10), and the gate electrode of the third transistor T3 is electrically connected to the gate line 900.

In the present application, in each pixel drive circuit 200, the gate electrode of the second transistor T2 and the gate electrode of the third transistor T3 are connected to the same gate line 900, which can effectively reduce the quantity of signal lines integrated in the drive backplane 000, which simplifies the preparation of the drive backplane 000. Because the timing of the loading signal of the data line 1000 connected to the first electrode of the second transistor T2 is different from the timing of the second electrode of the third transistor T3 and the sense signal line 800. Therefore, even though the second transistor T2 and the third transistor T3 are turned on or off simultaneously while being controlled by the gate line 900, the second transistor T2 and the third transistor T3 do not work simultaneously, ensuring that the drive backplane 000 can work properly.

In some embodiments of the present application, FIG. 11 is a schematic diagram of a film layer structure of a drive backplane according to some embodiments of the present application. As shown in FIG. 11, the drive backplane 000 includes: a substrate 100, and a first conductive layer D1, a buffering layer 1200, an active layer pattern D2, a gate insulating layer 1400, a second conductive layer D3, a passivation layer 700, a flat layer 1600, a third conductive layer D4, and a pixel definition layer 1700 disposed on the substrate 100 in a laminated direction vertically and distal from the substrate 100.

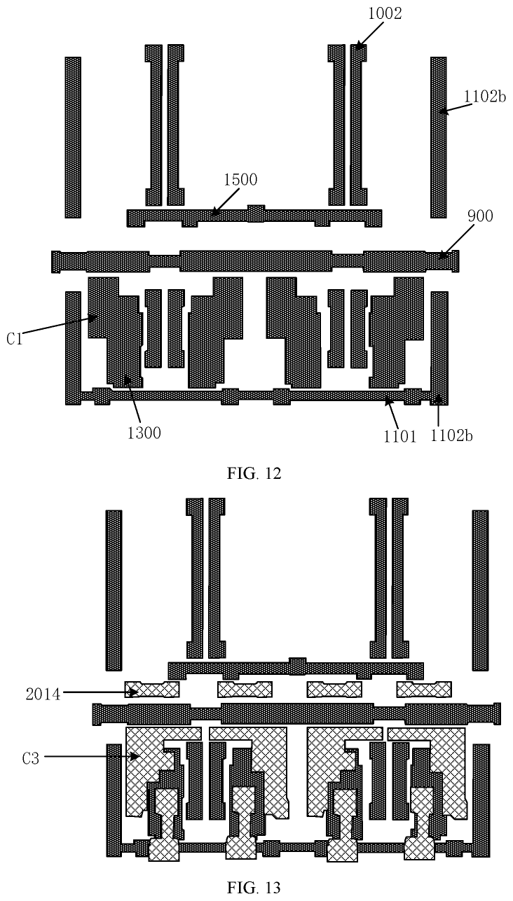

FIG. 12 is a top view of a first conductive layer according to some embodiments of the present application. As shown in FIG. 12, the first conductive layer D1 includes: a light shieling layer 1300, a gate line 900, a second sub-data line 1002, a first sub-power signal line 1101, a second signal line section 1102b, an auxiliary sense line 1500, and a capacitive electrode C1 in the above embodiment.

As shown in FIG. 13, FIG. 13 is a top view of a first conductive layer and an active layer that art stacked according to some embodiments of the present application. The active layer pattern D2 includes: the active layer 2014 of the transistor 201 and the auxiliary capacitive electrode C3 in the above embodiment.

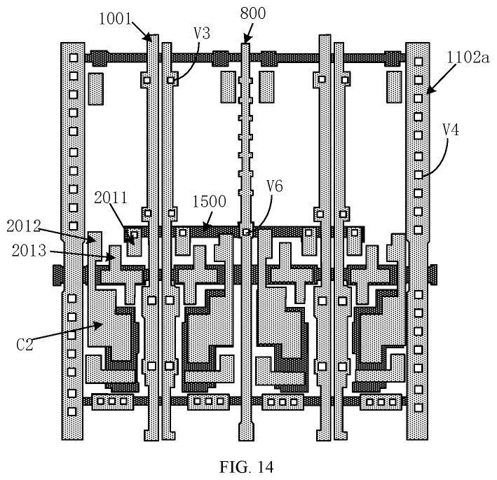

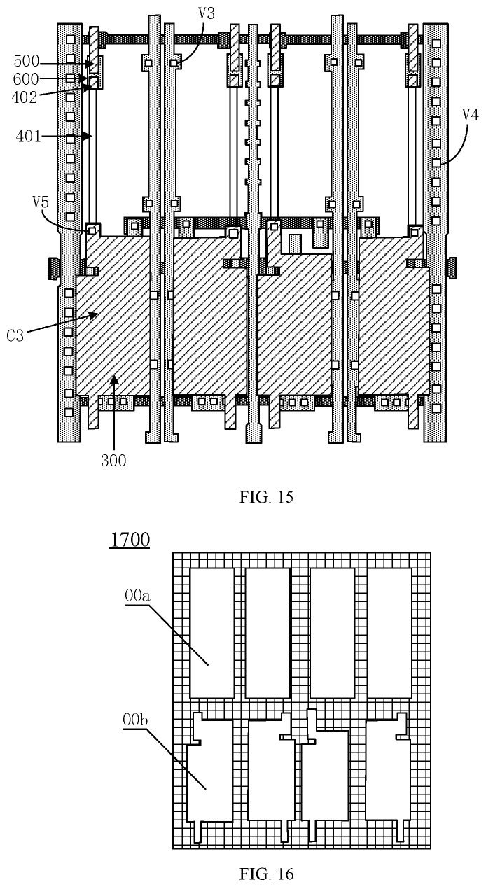

As shown in FIG. 14, FIG. 14 is a top view of a first conductive layer and a second conductive layer that are stacked according to some embodiments of the present application. The second conductive layer D3 includes: the first electrode 2011 of the transistor 201, the second electrode 2012 of the transistor 201, the gate electrode 2013 of the transistor 201, the first sub-data line 1001, the first signal line section 1102a, the sense line 800, and the capacitive electrode C2 in the above embodiment.

It is to be noted that the gate insulating layer between the second conductive layer D3 and the active layer pattern D2 has via holes V1, via holes V2, and via holes V6. The first electrode 2011 in the transistor 201 is electrically connected to the active layer 2014 in the transistor 201 through the via hole V1. The second electrode 2012 in the transistor 201 is electrically connected to the active layer 2014 through the via hole V2. The sense line 800 is electrically connected to the auxiliary sense line 1500 through the via hole V6.

As shown in FIG. 14, the gate insulating layer and buffering layer between the second conductive layer D3 and the first conductive layer D1 have via holes V3 and via holes V4. The first sub-data line 1001 is electrically connected to the second sub-data line 1002 through the via hole V3, and the first signal line section 1102a is electrically connected to the second signal line section 1102b through the via hole V4.

As shown in FIG. 11, the orthographic projection of the flat layer 1600 on the substrate 100 covers only the sub-pixel region 00b and is within the light transmitting region 00a. This prevents the organic material used to make the flat layer 1600 from aging and discoloring, which affects the light transmission in the light transmitting region 00a.

As shown in FIG. 15, FIG. 15 is a top view of a first conductive layer, a second conductive layer, and a third conductive layer that are stacked according to some embodiments of the present application. The third conductive layer D4 includes: the repair electrode 500, the auxiliary repair electrode 402, and the anode block 300 in the above embodiment.

It is noted that the passivation layer 700 and the flat layer 1600 between the second conductive layer D3 and the third conductive layer D4 have both a via hole V5 through which the anode block 300 is electrically connected to the second electrode 2012 of the transistor 201.

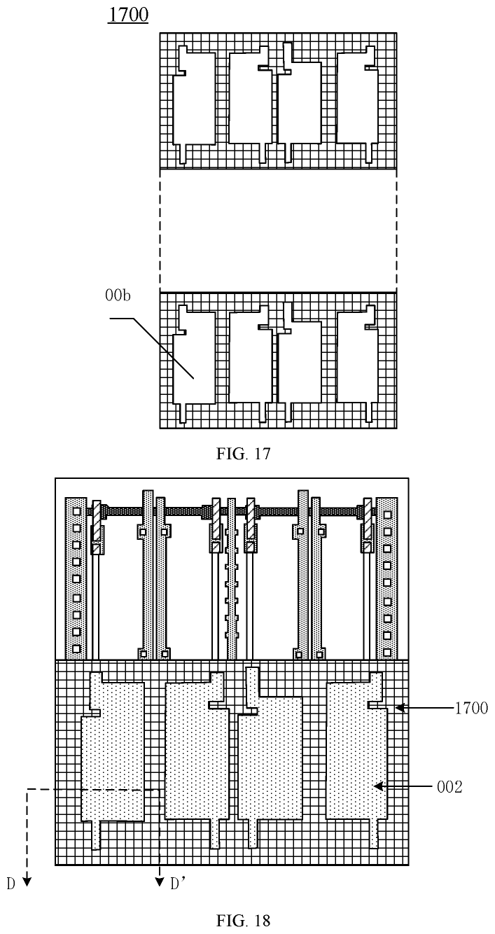

The pixel definition layer 1700 divides a plurality of sub-pixel regions 00b. The orthographic projection of the pixel definition layer 1700 on the substrate 100 is outside the transmitting region 00a. In this way, the organic material used for the pixel definition layer 1700 can be prevented from aging and discoloring, which can affect the light transmission of the light transmitting region 00a. In one possible implementation, as shown in FIG. 16, FIG. 16 is a top view of a pixel definition layer according to some embodiments of the present application. The pixel definition layer 1700 can also divide a plurality of light transmitting regions 00a. In this case, the locations corresponding to the gate lines 900, sense lines 800, power signal lines 1100, and data lines 1000 can also be arranged with the pixel definition layer 1700. In another possible line of sight approach, as shown in FIG. 17, FIG. 17 is a top view of another pixel definition layer according to some embodiments of the present application. The pixel definition layer 1700 is only divided into a plurality of sub-pixel regions 00b, and the pixel definition layer 1700 is not arranged in the region between any two adjacent light transmitting regions 00a.

In summary, embodiments of the present application provide a drive backplane, including: a substrate, a pixel drive circuit, an anode block, a repair line, and a repair electrode. In response to detecting that the pixel drive circuit in a sub-pixel region (e.g., a first sub-pixel region) is not functioning properly, the end of the repair line and the repair electrode in a light transmitting region adjacent to the first sub-pixel region can be heated by a laser repair device, such that the end of the repair wire and the repair electrode are fused together by heat. That is, the repair line and the repair electrode can be electrically connected to each other. In this way, the anode block in the first sub-pixel region is electrically connected to the anode block in the second sub-pixel region by the repair line and the repair electrode. In this way, during the process of the anode block in the second sub-pixel region being driven by the pixel drive circuit in the second sub-pixel region, the anode block in the second sub-pixel region can transmit the drive signal to the anode block in the first sub-pixel region, such that the pixel drive circuit in the second sub-pixel region can drive the anode blocks in the second sub-pixel region and the first sub-pixel region simultaneously. Therefore, in the case that the pixel drive circuit in the first sub-pixel region does not work properly, the anode block in the first sub-pixel region can be driven by the pixel drive circuit in the second sub-pixel region, such that the light-emitting device in the first sub-pixel region can also emit light properly, improving the yield rate of the display panel integrated with the drive backplane, and improving the display effect of the transparent display device integrated with the display panel.

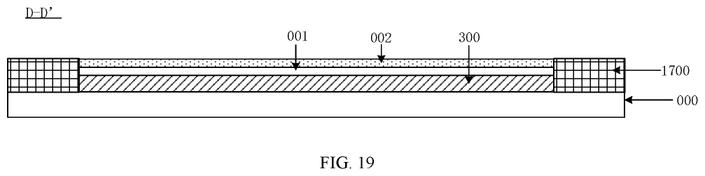

FIG. 18 is a schematic diagram of a display panel according to some embodiments of the present application. FIG. 19 is a cross-sectional view at D-D′ of the display panel illustrated in FIG. 18. Embodiments of the present application also provide a display panel, including: a drive backplane 000, a light emitting layer 001 and a cathode layer 002 disposed on the drive backplane 000. The drive backplane 000 is the drive backplane described in the above embodiments. It should be noted that the display panel in FIG. 18 is an example that the pixel definition layer 1700 is only divided into a plurality of sub-pixel regions 00b. The display panel can be an organic light emitting display (OLED) display panel or active matrix/organic light emitting diode (AM-OLED) display panel. In the case that the display panel is an OELD display panel or AM-OLED display panel, the display panel can be a top-emitting display panel or a bottom-emitting display panel.

Optionally, the display panel has a light-emitting device disposed in a sub-pixel region 00b. For a light-emitting device in a certain sub-pixel region 00b, the light-emitting device includes: an anode block 300 disposed in this sub-pixel region 00b, a portion of the light-emitting layer 001 disposed in the middle of the sub-pixel region, and a portion of the cathode layer 002 disposed in the sub-pixel region 00b.

Embodiments of the present application also provide a display device. The display device includes: a power supply assembly, the above display panel, and the power supply assembly configured to supply power to the display panel. The display device is: a transparent television, a transparent display or a transparent cell phone and any other products or components with transparent display function.

It should be noted that in the accompanying drawings, the dimensions of the layers and regions may be exaggerated for clarity of illustration. Also, it is understood that when a component or layer is referred to as being “on” another component or layer, it may be directly over the other component, or an intermediate layer may exist. Also, it is understood that when an element or layer is referred to as being “under” another element or layer, it may be directly under other elements, or there may be more than one intermediate layer or element. It is also understood that when a layer or element is referred to as being “between” two layers or elements, it may be the only layer between two layers or elements, or there may be more than one intermediate layer or element. Similar reference marks throughout indicate similar components.

The term “at least one of A and B” in this application is simply a description of the association relationship of the associated objects, indicating that three relationships can exist, for example, at least one of A and B, which can mean: A alone, both A and B, and B alone.

It should be noted that in the accompanying drawings, the dimensions of the layers and regions may be exaggerated for the clarity of the illustrations. It should be understood that when a component or layer is referred to as being “on” another component or layer, it may be directly over the other component, or there may be an intermediate layer. It should be understood that when an element or layer is referred to as being “under” another element or layer, it may be directly under other elements, or there may be more than one intermediate layer or element. It should also be understood that when a layer or element is referred to as being “between” two layers or elements, it may be the only layer between two layers or elements, or there may be more than one intermediate layer or element. Similar reference marks throughout indicate similar components.

In this application, the terms “first” and “second” are used for descriptive purposes only and are not to be construed as indicating or implying relative importance. The term “plurality” refers to two or more, unless otherwise expressly limited.

The above mentioned are only optional embodiments of the present application and are not used to limit the present application. Any modification, equivalent replacement, improvement, etc. made within the spirit and principles of the present application shall be included in the scope of protection of the present application.

1. A drive backplane, comprising:
a substrate, comprising a plurality of light transmitting regions and a plurality of sub-pixel regions;
a pixel drive circuit and an anode block that are disposed in the sub-pixel region, the pixel drive circuit being electrically connected to the anode block; and
repair lines and repair electrodes that are disposed in the light transmitting regions, an end of the repair line being spaced from the repair electrode;
wherein, for any of the repair lines and the repair electrodes in the light transmitting region, an end, departing from the repair electrode, of the repair line is electrically connected to the anode block in a first sub-pixel region, the repair electrode is electrically connected to the anode block in a second sub-pixel region, wherein the first sub-pixel region is a sub-pixel region of the plurality of sub-pixel regions disposed on one side of the light transmitting region, and the second sub-pixel region is a sub-pixel region the plurality of sub-pixel regions disposed on the other side of the light transmitting region.

2. The drive backplane according to claim 1, wherein at least some of the repair lines and the repair electrodes are arranged in a same layer as the anode block and are made of a same material as the anode block.

3. The drive backplane according to claim 2, wherein the repair line comprises a repair line body, and an auxiliary repair electrode connected to an end, close to the repair electrode, of the repair line body, the auxiliary repair electrode being spaced from the repair electrode;
wherein the repair line body is made of a transparent conductive material, and the auxiliary repair electrode is arranged in a same layer as the repair electrode and is made of a same material as the repair electrode.

4. The drive backplane according to claim 3, wherein the repair line body is closer to the substrate relative to the auxiliary repair electrode, an orthographic projection of the auxiliary repair electrode on the substrate is within an orthographic projection of the repair line body on the substrate, and an orthographic projection of the repair line body on the substrate is overlapped with an orthographic projection of the anode block in the first sub-pixel region on the substrate.

5. The drive backplane according to claim 3, further comprising: a landing electrode disposed in the light transmitting region, wherein at least one of the auxiliary repair electrode and the repair electrode is insulated from the landing electrode, the landing electrode is closer to the substrate relative to the repair line body, and an orthographic projection of the repair electrode on the substrate and an orthographic projection of the auxiliary repair electrode on the substrate are within an orthographic projection of the landing electrode on the substrate.

6. The drive backplane according to claim 1, wherein the repair electrode and the anode block in the second sub-pixel region are in an integral structure.

7. The drive backplane according to claim 1, wherein at least two adjacent sub-pixel regions are configured to form a pixel region, and the drive backplane further comprises a plurality of sense signal lines disposed on the substrate, one of the sense signal line being electrically connected to each of the pixel drive circuits in a row of the pixel regions;
wherein in response to the repair line in the light transmitting region adjacent to the sense signal line being disposed on a side, close to the sense signal line, of the light transmitting region, a plurality of bumps are defined on a side, close to the light transmitting region, of the sense signal line.

8. The drive backplane according to claim 1, wherein the pixel drive circuit comprises a plurality of transistors disposed in a same layer, each of the transistors comprising a first electrode, a second electrode, and a gate electrode, wherein the first electrode, the second electrode, and the gate electrode are disposed in a same layer and are made of a same material.

9. The drive backplane according to claim 8, wherein the transistor further comprises an active layer, wherein the active layer is insulated from the gate electrode and coupled to the first electrode and the second electrode; and
the drive backplane further comprises a light shieling layer disposed in the sub-pixel region, wherein the light shielding layer is closer to the substrate relative to the transistor, and in one sub-pixel region, an orthographic projection of a channel region in the active layer of at least one of the transistors of the pixel drive circuit on the substrate is within an orthographic projection of the light shieling layer on the substrate.

10. The drive backplane according to claim 9, wherein the pixel drive circuit further comprises a storage capacitor, comprising two capacitor electrodes opposite to each other, wherein one of the two capacitor electrodes is arranged in a same layer as the light shieling layer and is made of a same material as the light shieling layer, and the other of the two capacitor electrodes is arranged in a same layer as the gate electrode and is made of a same material as the gate electrode.

11. The drive backplane according to claim 10, wherein the active layer is closer to the substrate relative to the gate electrode, and an auxiliary capacitor electrode is disposed between the two capacitor electrodes, wherein the auxiliary capacitor electrode is insulated from each of the capacitor electrodes, and the auxiliary capacitor electrode is arranged in a same layer as the active layer and is made of a same material as the active layer.

12. The drive backplane according to claim 11, further comprising: a buffering layer, disposed between the auxiliary capacitor electrode and one of the two capacitor electrodes, and a gate insulating layer disposed between the auxiliary capacitor electrode and the other of the two capacitor electrodes, wherein the buffering layer is closer to the substrate relative to the gate insulating layer.

13. The drive backplane according to claim , further comprising: a plurality of gate lines and a plurality of data lines that are disposed on the substrate, wherein the gate line is electrically connected to each of the pixel drive circuits in one row of the sub-pixel regions, and the data line is electrically connected to each of the pixel drive circuits in one column of the sub-pixel regions;
wherein the gate line is arranged in a same layer as the light shieling layer and is made of a same material as the light shieling layer, and the data line comprises a first sub-data line and a second sub-data line that are stacked and electrically connected to each other, the first sub-data line is arranged in a same layer as the first electrode and the second electrode of the transistor and is made of a same material as the first electrode and the second electrode of the transistor, and the second sub-data line is arranged in a same layer as the gate line and is made of a same material as the gate line.

14. The drive backplane according to claim 13, further comprising: power signal lines disposed on the substrate, wherein the power signal line comprises: a plurality of first sub-power signal lines disposed parallel to the gate lines, and a plurality of second sub-power signal lines disposed parallel to the data lines, the first sub-power line is electrically connected to the second sub-power signal line, and the first sub-power signal line is electrically connected to each of the pixel drive circuits in one row of the sub-pixel regions.

15. The drive backplane according to claim 14, wherein the second sub-power signal line comprises a first signal line section and a second signal line section that are stacked and electrically connected to each other, wherein the first signal line section is arranged in a same layer as the first electrode and second electrode of the transistor and is made of a same material as the first electrode and second electrode of the transistor, the second signal line section and the first sub-power signal line are arranged in a same layer as the gate line and are made of a same material as the gate line.

16. A display panel, comprising: a drive backplane, a light emitting layer and a cathode layer disposed on the drive backplane, wherein the drive backplane comprises:
a substrate, comprising a plurality of light transmitting regions and a plurality of sub-pixel regions;
a pixel drive circuit and an anode block that are disposed in the sub-pixel region, the pixel drive circuit being electrically connected to the anode block; and
repair lines and repair electrodes that are disposed in the light transmitting regions, an end of the repair line being spaced from the repair electrode;
wherein, for any of the repair lines and the repair electrodes in the light transmitting region, an end, departing from the repair electrode, of the repair line is electrically connected to the anode block in a first sub-pixel region, the repair electrode is electrically connected to the anode block in a second sub-pixel region, wherein the first sub-pixel region is a sub-pixel region of the plurality of sub-pixel regions disposed on one side of the light transmitting region, and the second sub-pixel region is a sub-pixel region the plurality of sub-pixel regions disposed on the other side of the light transmitting region.

17. The display panel according to claim 16, wherein at least some of the repair lines and the repair electrodes are arranged in a same layer as the anode block and are made of a same material as the anode block.

18. The display panel according to claim 17, wherein the repair line comprises a repair line body, and an auxiliary repair electrode connected to an end, close to the repair electrode, of the repair line body, the auxiliary repair electrode being spaced from the repair electrode;
wherein the repair line body is made of a transparent conductive material, and the auxiliary repair electrode is arranged in a same layer as the repair electrode and is made of a same material as the repair electrode.

19. The display panel according to claim 18, wherein the repair line body is closer to the substrate relative to the auxiliary repair electrode, an orthographic projection of the auxiliary repair electrode on the substrate is within an orthographic projection of the repair line body on the substrate, and an orthographic projection of the repair line body on the substrate is overlapped with an orthographic projection of the anode block in the first sub-pixel region on the substrate.

20. The display panel according to claim 18, wherein the drive backplane further comprises: a landing electrode disposed in the light transmitting region, wherein at least one of the auxiliary repair electrode and the repair electrode is insulated from the landing electrode, the landing electrode is closer to the substrate relative to the repair line body, and an orthographic projection of the repair electrode on the substrate and an orthographic projection of the auxiliary repair electrode on the substrate are within an orthographic projection of the landing electrode on the substrate.
